(19) United States
(12) Patent Application Publication
(10) Pub. No.: US 2020/0212910 A1
(43) Pub. Date: Jul. 2, 2020

(54) TRANSISTOR SWITCH CIRCUIT

(71) Applicant: NUVOTON TECHNOLOGY CORPORATION, Hsinchu City (TW)

(72) Inventor: Wei-Jean LIU, TOUFEN CITY (TW)

(21) Appl. No.: 16/580,157

(22) Filed: Sep. 24, 2019

(30) Foreign Application Priority Data
Dec. 26, 2018 (TW) 107147227

(51) Int. Cl. H03K 17/687; H03K 17/06

(52) U.S. Cl. CPC H03K 17/6871; H03K 17/063

(57) ABSTRACT

A transistor switch circuit includes a first transistor and a set of serially connected transistors. By the configuration of the set of serially connected transistors, the conduction paths of the body diodes of the first transistor can be cut and the body effect thereof is eliminated. Hence, the output signal is prevented from leaking via the conduction path while the first transistor is turned off.

### CROSS-REFERENCE TO RELATED APPLICATION

This application claims priority from Taiwan Patent Application No. 107147227, filed on Dec. 26, 2018, in the Taiwan Intellectual Property Office, the content of which is hereby incorporated by reference in its entirety for all purposes.

### BACKGROUND OF THE INVENTION

### 1. Field of the Invention

The present invention relates to a transistor switch circuit, more particularly to a transistor switch circuit which eliminates the body effect by connecting body terminals of separate transistors to each other.

### 2. Description of the Related Art

Generally, a body effect of a transistor leads to the occurrence of current and voltage leakage, thus causing output voltage even when the transistor is turned off. A conventional solution is usually to use two transistors serially-connected to each other in a back-to-back manner to eliminate the body effect. This solution can successfully eliminate the body effect of each transistor, but result in the increase in conduction resistance of the entire circuit. How to make the balance between the reduction of conduction resistance and the elimination of the body effect has become an issue yet to be solved.

The method stated in U.S. Pat. No. 7,760,007B2 utilizes a bias circuit connected between two transistors to eliminate the body effect and current leakage; this method, however, requires an additional bias current circuit to provide current in order to drive the bias circuit, leading to the increase in the size of the whole circuit.

Accordingly, the inventor of the present invention has designed a transistor switch circuit in an effort to tackle with deficiencies in prior art and further to enhance the implementation and application in industries.

### SUMMARY OF THE INVENTION

In view of the aforementioned problems, the present invention aims to provide a transistor switch circuit to solve the conventional problems.

Based on the stated purpose, the present invention provides a transistor switch circuit, including a first transistor and a set of serially-connected transistors. The first transistor is coupled between an input terminal and an output terminal to control transmission and interruption of a signal between the input terminal and the output terminal. The set of serially-connected transistors is parallel to the first transistor and coupled between the input terminal and the output terminal. The set of serially-connected transistors includes a plurality of transistors which are back-to-back connected. A body terminal of each of the plurality of transistors is coupled to a first body terminal of the first transistor in order to cut off the conduction path of a body diode of the first transistor, thus eliminating the body effect. This prevents voltage or current leakage via the conduction path of the body diode when the transistor is turned off, and further decreases the value of the conduction resistance.

Preferably, the set of serially-connected transistors includes a second transistor and a third transistor connected to the second transistor in a back-to-back manner; a serially-connected node of the second transistor and the third transistor, a second body terminal of the second transistor, and a third body terminal of the third transistor are coupled to the first body terminal.

Preferably, the second transistor has a second source terminal and a second drain terminal, and the third transistor has a third source terminal and a third drain terminal; the second source terminal is connected to the third source terminal, the second drain terminal is connected to the input terminal, and the third drain terminal is connected to the output terminal.

Preferably, the set of serially-connected transistors further includes a fourth transistor and a fifth transistor. The fourth transistor is connected to one terminal, which is opposite to the third transistor, of the second transistor in a back-to-back manner, and the fourth transistor has a fourth body terminal, a fourth source terminal, and a fourth drain terminal; the fourth body terminal is connected to one, which is not coupled to the second transistor, of the fourth source terminal and the fourth drain terminal. The fifth transistor is connected to one terminal, which is opposite to the second transistor, of the third transistor in a back-to-back manner, and the fifth transistor has a fifth body terminal, a fifth source terminal, and a fifth drain terminal; the fifth body terminal is connected to one, which is not coupled to one terminal of the third transistor, of the fifth source terminal and the fifth drain terminal.

Based on the stated purpose, the present invention provides a transistor switch circuit, including a first transistor and a set of serially-connected transistors. The first transistor is coupled between an input terminal and an output terminal to control transmission and interruption of a signal between the input terminal and the output terminal. The set of serially-connected transistors is parallel to the first transistor and coupled between the input terminal and the output terminal. The set of serially-connected transistors includes a plurality of transistors which are back-to-back connected, wherein a first body terminal of the first transistor is coupled to a first serially-connected node of the plurality of transistors in order to cut off the conduction path of the body diode of the first transistor, thus eliminating the body effect. This prevents voltage or current leakage via the conduction path of the body diode when the transistor is turned off, and further decreases the conduction resistance value of the transistor switch circuit.

Preferably, the plurality of transistors include a second transistor and a third transistor connected to the second transistor in a back-to-back manner, and the first body terminal is coupled to a first serially-connected node between the second transistor and the third transistor.

Preferably, the plurality of transistors further comprise a fourth transistor and a fifth transistor; the fourth transistor is connected to one terminal, which is opposite to the third transistor, of the second transistor in a back-to-back manner, and the fourth transistor has a fourth body terminal coupled to a second body terminal of the second transistor and a second serially-connected node between the second transistor and the fourth transistor; the fifth transistor is connected to one terminal, which is opposite to the second transistor, of the third transistor in a back-to-back manner, and the fifth transistor has a fifth body terminal coupled to a third body terminal of the third transistor and also coupled to a third serially-connected node between the third transistor and the fifth transistor.

Preferably, the fourth transistor has a fourth source terminal and a fourth drain terminal, and the fifth transistor has a fifth source terminal and a fifth drain terminal; one, which is not coupled to the second transistor, of the fourth source terminal and the fourth drain terminal is coupled to the input terminal, and one, which is not coupled to the second transistor, of the fifth source terminal and the fifth drain terminal is coupled to the output terminal.

Preferably, the first transistor has a size larger than the size of each of the plurality of transistors in the set of serially-connected transistors.

Preferably, the first transistor has conduction resistance smaller than the conduction resistance of each of the plurality of transistors in the set of serially-connected transistors.

As stated, the transistor switch circuit of the present invention is able to cut off the conduction paths of the body diodes of the first transistor by connecting the body terminal of the first transistor to the body terminal of each transistor, thus eliminating the body effect. This prevents voltage or current leakage via the conduction paths of the body diodes when the transistor is turned off, and further decreases the conduction resistance value.

### BRIEF DESCRIPTION OF THE DRAWINGS

FIG. 1 depicts a circuit diagram of the transistor switch circuit according to the first embodiment of the present invention.

FIG. 2 depicts a circuit diagram illustrating a conventional source-to-source terminal circuit.

FIG. 3 depicts a voltage-waveform diagram of the transistor switch circuit according to the first embodiment of the present invention.

FIG. 4 depicts a circuit diagram of the transistor switch circuit according to the second embodiment of the present invention.

FIG. 5 depicts a circuit diagram of the transistor switch circuit according to the third embodiment of the present invention.

FIG. 6 depicts a circuit diagram of the transistor switch circuit according to the fourth embodiment of the present invention.

FIG. 7 depicts a circuit diagram of the transistor switch circuit according to the fifth embodiment of the present invention.

### DESCRIPTION OF THE PREFERRED EMBODIMENTS

It is to be understood that the advantages, features, and technical methods of the present invention are explained in more detail with reference to the exemplary embodiments and the drawings. Moreover, the present invention may be realized in different forms and should not be construed as the embodiments limited herein. On the contrary, for those of ordinary skill in the art, the embodiments provided will help convey the scope of the present invention more thoroughly, comprehensively, and completely. Furthermore, the present invention will be defined only by the scope of the appended claims.

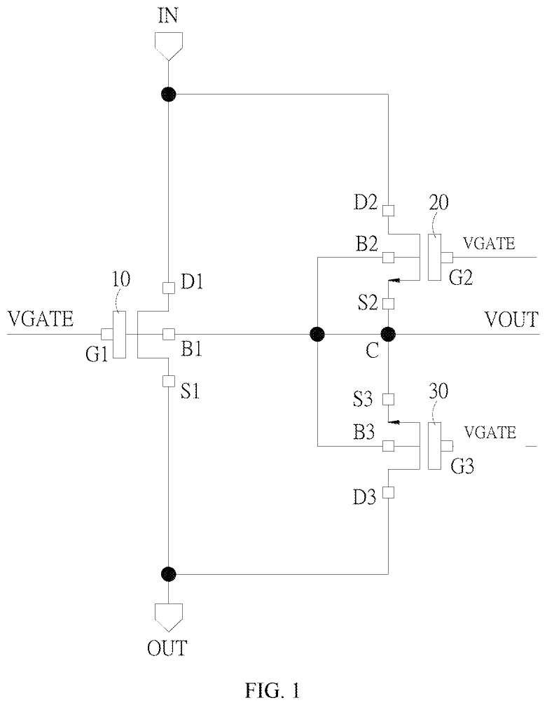

Please refer to FIG. 1, which depicts a circuit diagram of the transistor switch circuit according to the first embodiment of the present invention. As shown in FIG. 1, the transistor switch circuit the present invention includes a first transistor 10 and a set of serially-connected transistors. The first transistor 10 is coupled between an input terminal IN and an output terminal OUT to control transmission and interruption of a signal between the input terminal IN and the output terminal OUT; the first transistor 10 has a first source terminal S1, a first drain terminal D1, a first gate terminal G1, and a first body terminal B1. The set of serially-connected transistors is parallel to the first transistor 10 and coupled between the input terminal IN and the output terminal OUT. The set of serially-connected transistors includes a plurality of transistors including a second transistor 20 and a third transistor 30 that are back-to-back connected. A serially-connected node C of the second transistor 20 and the third transistor 30, a second body terminal B2 of the second transistor 20, and a third body terminal B3 of the third transistor 30 are mutually coupled to the first body terminal B1. The gate terminals of the first, second, and third transistors receive a control voltage VGATE and are not coupled to the input terminal IN and the output terminal OUT, so as to cut off the conduction path of the body diode of the first transistor 10, and further eliminate the body effect. This configuration of the transistor switch circuit of the invention can prevent the signal from transmitting from the input terminal IN to the output terminal OUT when the first transistor 10 is turned off.

The signal from the input terminal IN to the output terminal OUT is mainly transmitted through the first transistor 10, and the second transistor 20 and the third transistor 30 are only responsible for obstructing a small current leakage. Therefore, in order to implement the embodiment, the size of the first transistor 10 can be larger than the size of the second transistor 20 and the third transistor 30, so that the conduction resistance of the first transistor 10 can be smaller than the conduction resistance of the second transistor 20 and the third transistor 30. In addition, the second transistor 20 has a second source terminal S2, a second drain terminal D2, and a gate terminal G2; the third transistor has a third source terminal S3, a third drain terminal D3, and a third gate terminal G3. The second source terminal S2 is connected to the third source terminal S3, the second drain terminal D2 is connected to the input terminal IN, and the third drain terminal D3 is connected to the output terminal OUT.

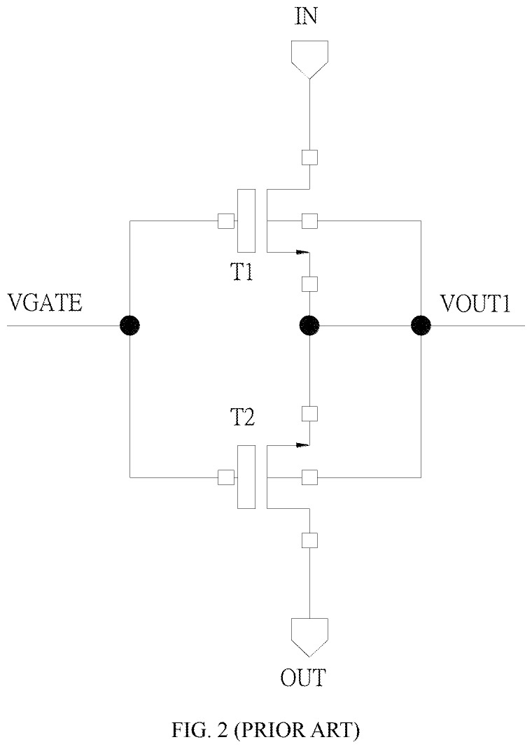

Please refer to FIG. 2, which depicts a circuit diagram illustrating a conventional source-to-source terminal circuit. As shown in FIG. 2, the conventional source-to-source terminal circuit utilizes the method of serially-connecting the source terminals of the transistors T1 and T2 and connecting the body terminals thereof to each other in an attempt to eliminate the body effect of the transistors T1 and T2. This prevents the signal from transmitting from the input terminal IN to the output terminal OUT when the transistors T1 and T2 are turned off.

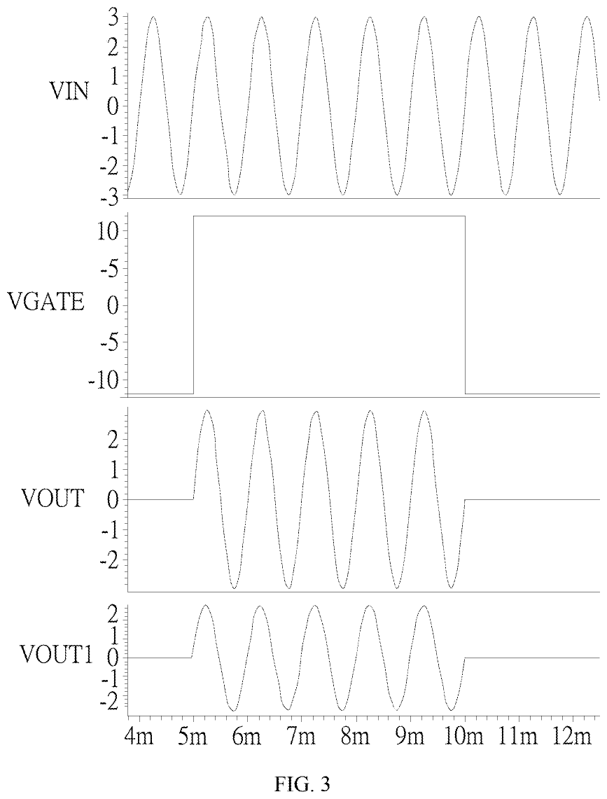

Please refer to FIG. 3, which depicts a voltage-waveform diagram of the transistor switch circuit according to the first embodiment of the present invention. As shown in FIG. 3, when equivalent input voltages VIN are applied to the input terminals IN of the circuits shown in FIGS. 1 and 2, the conduction of the second transistor 20 and the third transistor 30 is controlled by the control voltage VGATE, and similarly, the conduction of the transistors T1 and T2 shown in FIG. 2 is controlled by the control voltage VGATE. As shown in FIG. 3, the control voltage VGATE is changed to zero at 10 ms, and at the same time, the voltage VOUT and the voltage VOUT1 are also changed to zero, and it means that the transistor switch circuit of the present invention can eliminate the body effect of the first transistor 10.

In a condition that the transistor switch circuit of the present invention and the conventional source-to-source terminal circuit both are implemented with identical or similar areas, the conduction resistance of the transistor switch circuit of the present invention can be smaller than that of the conventional source-to-source terminal circuit, because the conduction resistance of the transistor is inversely proportional to the size, and the first transistor 10 in a larger size can be selected to be parallel to the second transistor 20 and the third transistor 30 in smaller sizes, and the signal is mainly transmitted through the first transistor 10, which occupies most of area of the transistor switch circuit, between the input terminal IN and the output terminal OUT. For instance, under a condition that each of the transistors T1 and T2 in FIG. 2 is designed with an 86-unit area, a total area of the transistors T1 and T2 is 172 units; a value of the conduction resistance of each of the transistors T1 and T2 is 1 ohm, a sum of the conduction resistance values between the input terminal IN and the output terminal OUT is equivalent to two 1-ohm resistances in series, which is 2 ohms. In contrast, in the embodiment of FIG. 1, the first transistor 10 may be implemented with a size of an 148-unit area, and each of the second transistor 20 and the third transistor 30 is implemented with a size of an 8-unit area, and a total area of the first transistor 10, the second transistor 20 and the third transistor 30 is 164 units, which is slightly smaller than that of the conventional source-to-source terminal circuit. The value of the conduction resistance of the first transistor 10 can be calculated according to the conduction resistance of the transistor T1 in FIG. 2 and the rule of the conduction resistance of the transistor being inversely proportional to the size, and the calculation result is 0.58 ohms approximately (1 Ω*86÷148≈0.58 Ω), whereas the conduction resistance of each of the second transistor 20 and the third transistor 30 is 10.75 ohms approximately (1 Ω*86÷8≈10.75 Ω). According to the calculation equation of serial and parallel resistance, the value of the total conduction resistance between the input terminal IN and the output terminal OUT is approximately 0.56 ohms. In other words, compared with the conventional source-to-source terminal circuit, the value of the conduction resistance of the transistor switch circuit of the present invention is reduced to 28% (0.56/2), which is nearly 4 times smaller under the condition of the total area of the transistor switch circuit of the present invention slightly smaller than that of the conventional source-to-source terminal circuit.

In an embodiment, the first transistor of the transistor switch circuit of the present invention can occupy at least 80% of the area (or size) of the transistor switch circuit.

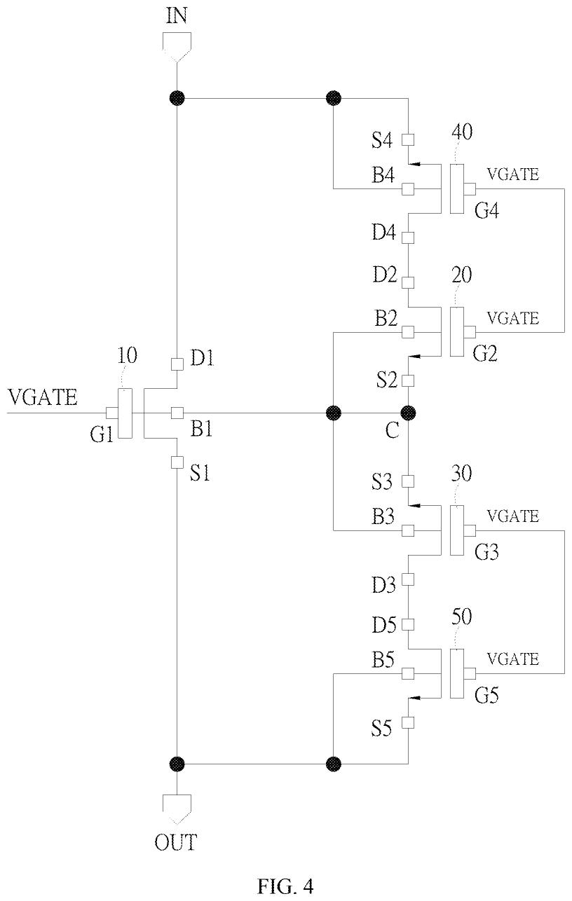

Please refer to FIG. 4, which depicts a circuit diagram of the transistor switch circuit according to the second embodiment of the present invention. As shown in FIG. 4, the transistor switch circuit further includes a fourth transistor 40 and a fifth transistor 50. The fourth transistor 40 is connected to one terminal, which is opposite to the third transistor 30, of the second transistor 20 in a back-to-back manner, and the fourth transistor 40 has a fourth body terminal B4, a fourth source terminal S4, a fourth drain terminal D4, and a fourth gate terminal G4. The fourth body terminal B4 is connected to the fourth source terminal S4, and the fourth gate terminal G4 is connected to the second gate terminal G2. The fifth transistor 50 is connected to one terminal, which is opposite to the second transistor 20, of the third transistor 30 in a back-to-back manner, and the fifth transistor has a fifth body terminal B5, a fifth source terminal S5, a fifth drain terminal D5, and a gate terminal G5. The fifth body terminal B5 is connected to the fifth source terminal S5, and the fifth gate terminal G5 is connected to the third gate terminal G3. In other embodiment, the fourth body terminal B4 may be connected to the fourth drain terminal D4, and the fifth body terminal B5 can also be connected to the fifth drain terminal D5 according to the requirement of the circuit design, which is not limited to the scope of the present invention. Owing to the increase in the number of transistors, the range in which the voltage on the node C can be adjusted may be increased, and the body effect of the first transistor 10 may be eliminated as well. In the second embodiment, the first transistor 10 has a size larger than the size of each of the transistors 20, 30, 40 and 50.

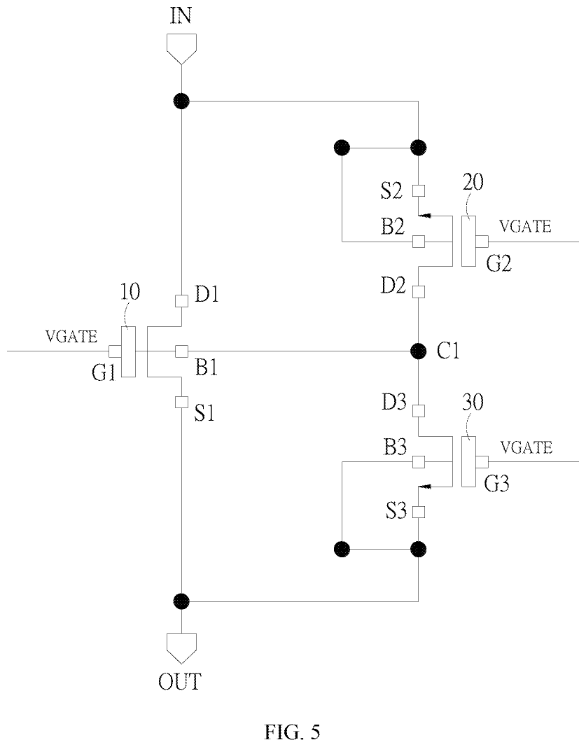

Please refer to FIG. 5, which depicts a circuit diagram of the transistor switch circuit according to the third embodiment of the present invention. As shown in FIG. 5, the third embodiment, the same as the first embodiment, of the present invention includes the first transistor 10, the second transistor 20, and the third transistor 30, but the connection structure of the third embodiment differs from that of the first embodiment. The connection structure is illustrated as follows. The first body terminal B1 is coupled to a first serially-connected node C1 between the second transistor 20 and the third transistor 30. The second body terminal B2 is connected to the second source terminal S2. The third body terminal B3 is connected to the third source terminal S3. This configuration has the same effect of eliminating the body effect of the first transistor 10, and prevents the signal from transmitting from the input terminal IN to the output terminal OUT when the transistors are turned off. In the third embodiment, the first transistor 10 has a size larger than the size of each of the transistors 20 and 30.

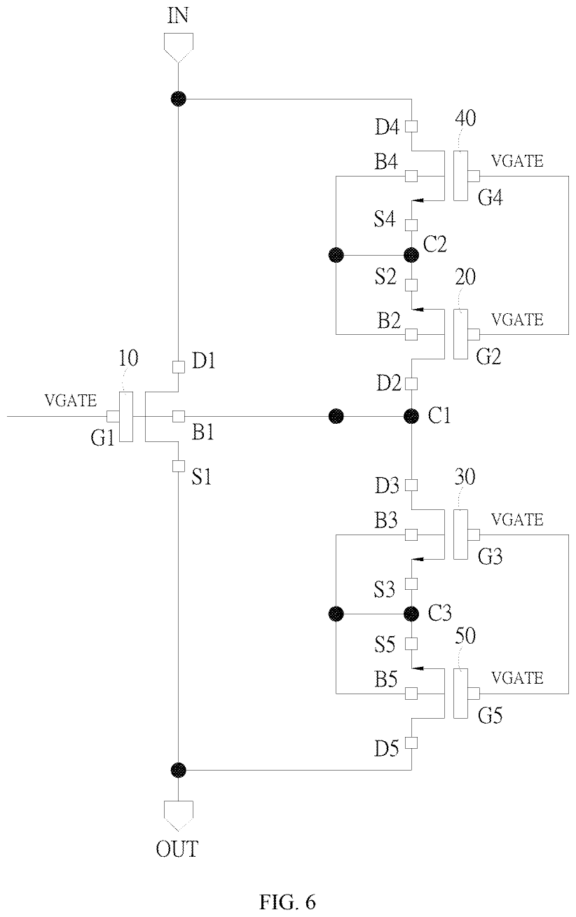

Please refer to FIG. 6, which depicts a circuit diagram of the transistor switch circuit according to the fourth embodiment of the present invention. As shown in FIG. 6, the fourth embodiment, the same as the second embodiment, of the present invention includes the fourth transistor 40 and the fifth transistor 50; likewise, the fourth transistor 40 is connected to one terminal, which is opposite to the third transistor 30, of the second transistor 20 in a back-to-back manner, and the fifth transistor 50 is connected to one terminal, which is opposite to the second transistor 20, of the third transistor 30 in a back-to-back manner. The fourth gate terminal G4 is connected to the second gate terminal G2, and the fifth gate terminal G5 is connected to the third gate terminal G3. However, the connection method of the fourth embodiment differs from that of the second embodiment. The connection method is illustrated as follows: The fourth body terminal B4 is coupled to the second body terminal B2 of the second transistor 20 and is also coupled to a second serially-connected node C2 between the second transistor 20 and the fourth transistor 40. The fourth source terminal S4 is connected to the second source terminal S2, and the fourth drain terminal D4 is coupled to the input terminal IN. The fifth body terminal B5 is coupled to the third body terminal B3 of the third transistor 30 and is also coupled to a third serially-connected node C3 between the third transistor 30 and the fifth transistor 50. The fifth source terminal S5 is connected to the third source terminal S3, and the fifth drain terminal D5 is coupled to the output terminal OUT. Owing to the increase in the number of transistors, the range in which the voltage on the node C1 can be adjusted may be increased, and the body effect of the first transistor 10 may be eliminated as well. In the fourth embodiment, the first transistor 10 has a size larger than the size of each of the transistors 20, 30, 40 and 50.

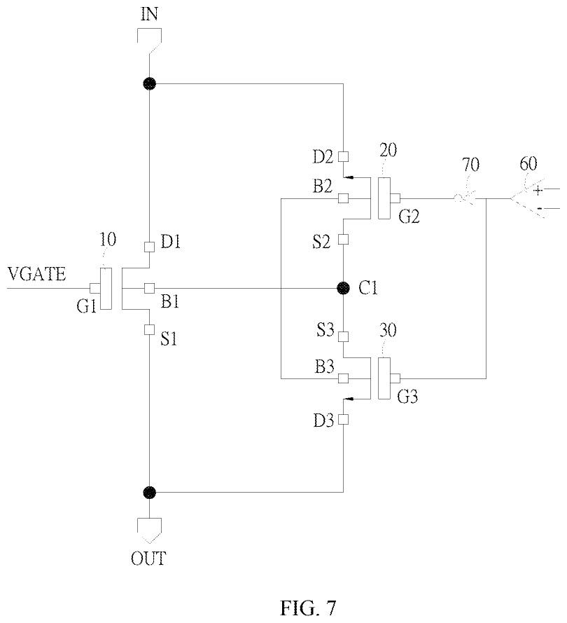

Please refer to FIG. 7, which depicts a circuit diagram of the transistor switch circuit according to the fifth embodiment of the present invention. As shown in FIG. 7, the fifth embodiment, the same as the first embodiment, of the present invention includes the first transistor 10, the second transistor 20, and the third transistor 30. Moreover, this embodiment further includes a comparator 60 and an inverter 70. The comparator 60 has a positive input terminal for receiving the voltage at the input terminal, and a negative input terminal for receiving the voltage at the output terminal, and an output terminal of the comparator 60 is connected to the inverter 70 and the third gate terminal G3 of the third transistor 30; the inverter 70 is connected to the second gate terminal G2 of the second transistor 20; the input terminal IN receives the input voltage VIN, and the output terminal OUT outputs the voltage VOUT. The configuration of the remaining elements is the same as that of the first embodiment. Since the configuration of the first embodiment differs from that of the first embodiment, the operating mechanism of the fifth embodiment of the present invention differs from that of the first embodiment. First, in a condition that the voltage at the output terminal is higher than the voltage at the input terminal before the control voltage VGATE becomes zero, the comparator 60 outputs low voltage (low level), which makes the third transistor 30 turned off, the inverter 70 outputs high voltage (high level) to make the second transistor 20 turned on, and the control voltage then becomes zero. Since the parasitic transistor of the second transistor 20 has reversely-biased voltage from the direction of the output terminal OUT to the input terminal IN, the transmission between the input terminal IN and the output terminal OUT can be cut after the control voltage becomes zero. Secondly, in a condition that and the voltage at the output terminal OUT is lower than the voltage at the input terminal IN before the control voltage VGATE is zero, the comparator 60 outputs high voltage (high level), which turns on the third transistor 30, the inverter 70 outputs low voltage (low level) to turn off the second transistor 20, and the control voltage then becomes zero. Since the parasitic transistor of the third transistor 30 has reversely-biased voltage from the direction of the input terminal IN to the output terminal OUT, the transmission between the input terminal IN and the output terminal OUT can be cut after the control voltage becomes zero. Simply stated, this configuration can also eliminate the body effect, and prevents the voltage at the input terminal IN form being transmitted to the output terminal OUT when the control voltage

VGATE is zero.

It should be noted that when the fifth embodiment of the present invention is applied to a high voltage circuit system, only the first transistor 10 is required to be a high voltage element, and the second transistor 20 and the third transistor 30 do not need to be high voltage elements, so that the selection for the second transistor 20 and the third transistor 30 becomes more flexible, thus reducing the manufacturing cost of the transistor switch circuit of the present invention. The high voltage and low voltage are opposite to each other rather than absolute values. For instance, the high voltage may be 5V, and the low voltage may be 3V or less. Thus, the value of the high voltage is higher than the value of the low voltage.

Accordingly, the transistor switch circuit of the present invention is able to cut off the conduction path of the body diode of the first transistor 10 by connecting the first body terminal B1 to the second body terminal B2 and the third body terminal B3, thus eliminating the body effect. This configuration prevents voltage or current leakage via the conduction path of the body diode when the first transistor 10 is turned off. Moreover, the feature of a low conduction resistance value may be achieved by the configuration regarding the size of the first transistor 10 being larger than the size of each of the second transistor 20 and the third transistor 30. Other embodiments of the present invention may also be applied according to requirement of circuit design to achieve the elimination the body effect of the transistor as well. In summary, the transistor switch circuit of the present invention has the advantages as described above which achieve the purpose of eliminating the body effect of the transistor.

The above description is merely illustrative rather than restrictive. Any equivalent modification or alteration without departing from the spirit and scope of the present invention should be included in the appended claims.

What is claimed is:

1. A transistor switch circuit, comprising:
a first transistor coupled between an input terminal and an output terminal and configured to control transmission and interruption of a signal between the input terminal and the output terminal; and
a set of serially-connected transistors parallel to the first transistor and coupled between the input terminal and the output terminal, the set of serially-connected transistors comprising a plurality of transistors which are back-to-back connected, wherein a body terminal of each of the plurality of transistors is coupled to a first body terminal of the first transistor.

2. The transistor switch circuit according to claim 1, wherein the plurality of transistors comprises:
a second transistor; and
a third transistor connected to the second transistor in a back-to-back manner;
wherein, a serially-connected node of the second transistor and the third transistor, a second body terminal of the second transistor, and a third body terminal of the third transistor are mutually coupled to the first body terminal.

3. The transistor switch circuit according to claim 2, wherein the second transistor has a second source terminal and a second drain terminal, and the third transistor has a third source terminal and a third drain terminal; the second source terminal is connected to the third source terminal, the second drain terminal is connected to the input terminal, and the third drain terminal is connected to the output terminal.

4. The transistor switch circuit according to claim 2, wherein the plurality of transistors further comprises:
a fourth transistor connected to one terminal, which is opposite to the third transistor, of the second transistor in a back-to-back manner, wherein the fourth transistor has a fourth body terminal, a fourth source terminal, and a fourth drain terminal, and the fourth body terminal is connected to one, which is not coupled to one terminal of the second transistor, of the fourth source terminal and the fourth drain terminal; and
a fifth transistor connected to one terminal, which is opposite to the second transistor, of the third transistor in a back-to-back manner, and the fifth transistor having a fifth body terminal, a fifth source terminal, and a fifth drain terminal, wherein the fifth body terminal is connected to one, which is not coupled to one terminal of the third transistor, the fifth source terminal and the fifth drain terminal.

5. The transistor switch circuit according to claim 1, wherein the first transistor has a size larger than the size of each of the plurality of transistors in the set of serially-connected transistors.

6. The transistor switch circuit according to of claim 1, wherein the first transistor has conduction resistance lower than conduction resistance of each of the plurality of transistors in the set of serially-connected transistors.

7. A transistor switch circuit, comprising:
a first transistor coupled between an input terminal and an output terminal to control transmission and interruption of a signal between the input terminal and the output terminal; and
a set of serially-connected transistors parallel to the first transistor and coupled between the input terminal and the output terminal, wherein the set of serially-connected transistors comprising a plurality of back-to-back connected transistors, and a first body terminal of the first transistor is coupled to a first serially-connected node of the plurality of transistors.

8. The transistor switch circuit according to claim 7, wherein the plurality of transistors comprise:
a second transistor; and
a third transistor connected to the second transistor in a back-to-back manner;
wherein the first body terminal is coupled to a first serially-connected node between the second transistor and the third transistor.

9. The transistor switch circuit according to claim 8, wherein the plurality of transistors further comprise:
a fourth transistor connected to one terminal, which is opposite to the third transistor, of the second transistor in a back-to-back manner, and the fourth transistor having a fourth body terminal, wherein the fourth body terminal is coupled to a second body terminal of the second transistor and is also coupled to a second serially-connected node between the second transistor and the fourth transistor; and
a fifth transistor connected to one terminal, which is opposite to the second transistor, of the third transistor in a back-to-back manner, and the fifth transistor having a fifth body terminal, wherein the fifth body terminal is coupled to a third body terminal of the third transistor and is also coupled to a third serially-connected node between the third transistor and the fifth transistor.

10. The transistor switch circuit according to claim 9, wherein the fourth transistor has a fourth source terminal and a fourth drain terminal, and the fifth transistor has a fifth source terminal and a fifth drain terminal, and one of the fourth source terminal and the fourth drain terminal is coupled to the input terminal, and one of the fifth source terminal and the fifth drain terminal is coupled to the output terminal.

11. The transistor switch circuit according to claim 7, wherein the first transistor has a size larger than the size of each of the plurality of transistors in the set of serially-connected transistors.

12. The transistor switch circuit according to claim 7, wherein the size of the first transistor is at least 80% of a size of the transistor switch circuit.

13. The transistor switch circuit according to claim 7, wherein the first transistor has a conduction resistance smaller than the conduction resistance of each of the plurality of transistors in the set of serially-connected transistors.
